(19) United States
(12) Patent Application Publication
(10) Pub. No.: US 2026/0331334 A1
(43) Pub. Date: Oct. 22, 2026

(54) WIRE HARNESS

(71) Applicant: SUMITOMO WIRING SYSTEMS, LTD., Yokkaichi-shi, Mie (JP)

(72) Inventors: Ryuta SAITO, Yokkaichi-shi (JP); Katsutoshi IZAWA, Yokkaichi-shi (JP); Kosuke TANAKA, Yokkaichi-shi (JP)

(73) Assignee: SUMITOMO WIRING SYSTEMS, LTD., Yokkaichi-shi, Mie (JP)

(21) Appl. No.: 19/112,386

(22) PCT Filed: Aug. 29, 2023
(86) PCT No.: PCT/JP2023/031279

§ 371 Date: Mar. 17, 2025

(30) Foreign Application Priority Data
Sep. 16, 2022 (JP) 2022-148159

(51) Int. Cl. H01B 9/02; B60R 16/02; H01R 4/34; H01R 4/64

(52) U.S. Cl. CPC H01B 9/028; B60R 16/0215; H01B 9/024; H01R 4/34; H01R 4/64; H05K 9/0098

(57) ABSTRACT

A wire harness that includes an electric wire; a braided tube that is tubular and that surrounds an outer circumference of the electric wire; and an earth terminal, wherein: an end of the braided tube includes an earth wire that does not surround the outer circumference of the electric wire and extends away from the electric wire, the earth terminal is attached to a front end of the earth wire, the earth terminal includes: a base that is made of metal and that includes a column around which the earth wire is wound and a flange that is integrally formed with the column; and a cover that is made of metal and that includes an insertion hole into which the column is inserted, and the cover is fixed to the base with the earth wire, which is wound around the column, sandwiched between the cover and the flange.

### BACKGROUND

The present disclosure relates to a wire harness.

A wire harness that includes a shielded electric wire (see, for example, JP2006-156299A) is conventionally known as one example of a wire harness arranged inside a vehicle, such as a hybrid vehicle or an electric vehicle. A shielded electric wire includes a braided member that surrounds the outer circumference of a covered electric wire and a sheath that surrounds the outer circumference of the braided member. The braided member has an electromagnetic shielding function of suppressing the radiation of electromagnetic waves (or “electromagnetic noise”) from the covered electric wire to the outside of the shielded electric wire.

With this type of wire harness, terminals of the sheath at ends in the length direction of the shielded electric wire are removed to expose the braided member, and the exposed braided member is separated from the covered electric wire. The braided member that has been separated from the covered electric wire in this way constructs an earth wire. The front end of this earth wire is connected by crimping to an earth terminal made of metal. This earth terminal is then earthed to a grounding point provided on the housing of a peripheral device, a vehicle body panel, or the like, thereby achieving a more stabilized electromagnetic shielding function for the shielded electric wire.

### SUMMARY

However, with a wire harness that uses the earthing structure described above, variations in the length of the earth wire may occur during manufacturing. For this reason, it would be desirable to develop a wire harness capable of absorbing such variations in the length of the earth wire.

An exemplary aspect of the disclosure provides a wire harness capable of absorbing variations in the length of an earth wire.

A wire harness according to an aspect of the present disclosure includes: an electric wire; a braided tube that is tubular and that surrounds an outer circumference of the electric wire; and an earth terminal, wherein: an end of the braided tube includes an earth wire that does not surround the outer circumference of the electric wire and extends away from the electric wire, the earth terminal is attached to a front end of the earth wire, the earth terminal includes: a base that is made of metal and that includes a column around which the earth wire is wound and a flange that is integrally formed with the column; and a cover that is made of metal and that includes an insertion hole into which the column is inserted, and the cover is fixed to the base with the earth wire, which is wound around the column, sandwiched between the cover and the flange.

A wire harness according to an aspect of the present disclosure achieves an effect of absorbing variations in the length of an earth wire.

### BRIEF DESCRIPTION OF THE DRAWINGS

FIG. 1 is a schematic diagram depicting a wire harness according to an embodiment.

FIG. 2 is a schematic side view of a wire harness according to an embodiment.

FIG. 3 is a schematic perspective view of a braided member of a wire harness according to an embodiment.

FIG. 4 is a schematic perspective view of a wire harness according to an embodiment.

FIG. 5 is a schematic exploded perspective view of a wire harness according to an embodiment.

FIG. 6 is a schematic cross-sectional view of a wire harness according to an embodiment.

FIG. 7 is a schematic cross-sectional view of a wire harness according to an embodiment.

FIG. 8 is a schematic plan view of a wire harness according to an embodiment.

FIG. 9 is a schematic plan view of a wire harness according to a modification.

FIG. 10 is a schematic perspective view of a wire harness according to a modification.

FIG. 11 is a schematic cross-sectional view of a wire harness according to a modification.

### DETAILED DESCRIPTION OF EMBODIMENTS

Outline of Embodiments of the Present Disclosure Several embodiments of the present disclosure will first be listed and described in outline.

(1) A wire harness according to an aspect of the present disclosure includes: an electric wire: a braided member that is tubular and surrounds an outer circumference of the electric wire; and an earth terminal, wherein an end of the braided member includes an earth wire that does not surround the outer circumference of the electric wire and extends away from the electric wire, the earth terminal is attached to a front end of the earth wire, the earth terminal includes: a base member that is made of metal and includes a column portion around which the earth wire is wound and a flange portion that is integrally formed with the column portion; and a cover member that is made of metal and includes an insertion hole into which the column portion is inserted, and the cover member is fixed to the base member with the earth wire, which is wound around the column portion, sandwiched between the cover member and the flange portion.

With this configuration, the earth wire is wound around the column portion of the base member, and the wound earth wire is sandwiched between the cover member and the flange portion, both of which are made of metal. By doing so, it is possible to electrically connect the earth wire wound around the column portion and the earth terminal to each other. However, during the manufacturing of a wire harness and the like, variations may occur in the length of the earth wire. As one example, the length by which the earth wire exceeds a standard dimension may vary. Even when this happens, the excess length of the earth wire can be easily absorbed by changing the length of the earth wire wrapped around the column portion. By doing so, even if there is variation in the length of the earth wire, such variation can be easily absorbed, which makes it possible to favorably prevent variation in the length from the base end of the earth wire to the earth terminal. In other words, the length from the base end of the earth wire to the earth terminal can be easily set to a standard dimension.

(2) For the wire harness according to (1) above, the earth wire may be wound around the outer circumference of the column portion over a range that exceeds one revolution, and the earth wire may include an overlapping portion where a first turn part and a second turn part that are wound around the outer circumference of the column portion overlap.

With this configuration, the earth wire is wound around the outer circumference of the column portion so as to have an overlapping portion where a first turn part and a second turn part of the earth wire wound around the outer circumference of the column portion overlap. Since the first turn of the earth wire and the second turn of the earth wire overlap at the overlapping portion, the earth wire, that is, the braided member, comes into contact with itself at a large number of points. Friction occurs at this large number of contact points, which makes the earth wire less susceptible to coming undone from the state where the earth wire is wound around the column portion. By doing so, it is possible to favorably maintain the state where the earth wire is wound around the column portion, and it is also possible to favorably maintain the state where the earth wire is sandwiched and fixed between the base member and the cover member. As a result, it is possible to improve the force fixing the earth terminal to the earth wire. This means that the state where the earth wire and the earth terminal are electrically connected to each other can be favorably maintained, and the reliability of the electrical connection between the earth wire and the earth terminal can be improved.

(3) For the wire harness according to (1) above, the earth wire may be wound around the outer circumference of the column portion over a range of less than one revolution, and the earth wire may be wound around the outer circumference of the column portion in a U-shape.

According to this configuration, the earth wire is wound around the outer circumference of the column portion in a U-shape. The braided member and the earth terminal can be electrically connected to each other via the earth wire wound in this U-shape.

(4) For the wire harness according to any one of (1) to (3) above, the braided member may have a structure in which a plurality of metal strands are woven, each of the plurality of metal strands may include a strand main body and a plating film that covers an outer circumferential surface of the wire strand, and a surface roughness of the outer circumferential surface of the plating film may be greater than a surface roughness of an outer circumferential surface of the strand main body.

According to this configuration, a plating film is formed on the surface of each metal strand that constructs the braided member, and the outer circumferential surface of each metal strand is formed with an increased surface roughness. By doing so, the coefficient of friction of the outer circumferential surface of each metal strand can be increased. This makes it possible to increase the friction between the metal strands and between the metal strands and the earth terminal (that is, the column portion). As a result, the earth wire becomes less susceptible to coming undone from the state where the earth wire is wound around the column portion. By doing so, it is possible to favorably maintain the state where the earth wire is wound around the column portion and the state where the earth wire is sandwiched and fixed between the base member and the cover member can be favorably maintained. As a result, it is possible to improve the force that fixes the earth terminal to the earth wire. This makes it possible to favorably maintain the state where the earth wire and the earth terminal are electrically connected to each other and to improve the reliability of the electrical connection between the earth wire and the earth terminal.

(5) The wire harness according to any one of (1) to (4) above may further include a fixing member for fixing the cover member onto the base member.

According to this configuration, the fixing member can favorably fix the cover member onto the base member. By doing so, it is possible to favorably maintain the state where the earth wire is sandwiched between the base member and the cover member, and to favorably maintain the state where the earth wire and the earth terminal are electrically connected to each other.

(6) For the wire harness according to (5) above, the column portion may be a tubular portion with a through hole that passes through the column portion in an axial direction, and the fixing member may be a bolt that is inserted into the through hole and fixes the earth terminal to a grounding point.

According to this configuration, the bolt, which is a fixing member for fixing the cover member onto the base member, also functions as a fixing member for fixing the earth terminal to the grounding point. That is, the bolt has both a function of fixing the cover member onto the base member and a function of fixing the earth terminal to the grounding point. For this reason, the number of components of the wire harness can be reduced compared to a configuration where the fixing member for fixing the cover member onto the base member and the fixing member for fixing the earth terminal to the grounding point are separate components.

(7) For the wire harness according to any one of (1) to (4) above, the cover member may be integrated with the base member.

According to this configuration, the cover member is integrated with the base member with the earth wire, which has been wound around the column portion, sandwiched between the cover member and the flange portion. This prevents the cover member from unintentionally coming off the base member. By doing so, it is possible to favorably maintain the state where the earth wire is sandwiched between the base member and the cover member and to favorably maintain the state where the earth wire and the earth terminal are electrically connected to each other.

(8) For the wire harness according to any one of (1) to (7) above, an outer circumferential surface of the flange portion may include a notch for positioning the earth terminal relative to an object to which the earth terminal is attached.

According to this configuration, a notch is provided on the outer circumferential surface of the flange portion. This means that by placing the earth terminal on the object to which the earth terminal is to be attached so that protrusions on the attachment object and the notch of the earth terminal engage each other, the earth terminal can be easily positioned relative to the attachment object. By doing so, the job of fixing the earth terminal to the attachment object is facilitated.

(9) For the wire harness according to any one of (1) to (8) above, the electric wire may be one out of a plurality of electric wires, the braided member may collectively surround an outer circumference of the plurality of electric wires, and the earth wire may extend away from the plurality of electric wires without surrounding the outer circumference of the plurality of electric wires.

According to this configuration, the outer circumference of the plurality of electric wires is collectively surrounded by the braided member. By electrically connecting the earth wire of such a braided member to an earth terminal, the braided member can function as an electromagnetic shield member for the plurality of electric wires.

### DETAILED DESCRIPTION OF EMBODIMENTS OF THE PRESENT DISCLOSURE

Specific examples of a wire harness according to the present disclosure are described below with reference to the drawings. In the drawings, parts of the structure may be exaggerated or simplified for ease of explanation. In addition, the ratios between the dimensions of parts may differ between individual drawings. In this specification, the expressions “parallel” and “perpendicular” do not refer simply to configurations that are strictly parallel or perpendicular, and also include states that are substantially parallel or perpendicular within a range where the effects of the present embodiment are still achieved. Note that the present disclosure is not limited to the illustrated examples and is instead indicated by the patent claims and intended to include all modifications within the meaning and scope of the patent claims and their equivalents.

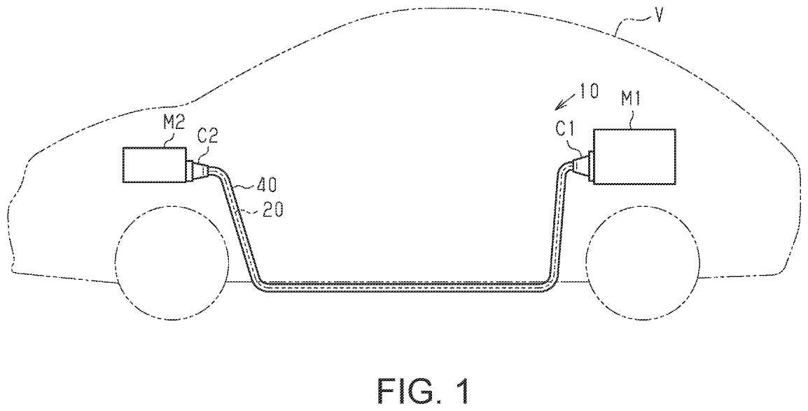

A wire harness 10 depicted in FIG. 1 is mounted in a vehicle V, such as a hybrid vehicle or an electric vehicle. The wire harness 10 electrically connects two or more vehicle-mounted devices to each other. The expression “vehicle-mounted devices” refers to electrical devices mounted in the vehicle V. As one example, the wire harness 10 electrically connects a high-voltage battery M1 installed at the rear of the vehicle V and an inverter M2 installed closer to the front of the vehicle V than the high-voltage battery M1. As one example, the high-voltage battery M1 is a battery capable of supplying a voltage of several hundred volts. The inverter M2 is connected to a wheel driving motor (not illustrated) that serves as a power source for driving the vehicle. The inverter M2 generates AC power from the DC power of the high voltage battery M1 and supplies this AC power to the motor. The wire harness 10 is formed with an elongated shape so as to extend as one example in the front-rear direction of the vehicle V.

As one example, the wire harness 10 includes an electric wire member 20, connectors C1 and C2 that are attached to both ends of the electric wire member 20, and an external member 40 that surrounds an outer circumference of the electric wire member 20. A first end in the length direction of the electric wire member 20 is connected via the connector C1 to the high-voltage battery M1 and a second end in the length direction of the electric wire member 20 is connected via the connector C2 to the inverter M2.

The external member 40 is in the overall shape of an elongated tube. As one example, the external member 40 internally houses an intermediate part in the length direction of the electric wire member 20. In other words, the electric wire member 20 passes through the inside of the external member 40. The external member 40 has a function of protecting the electric wire member 20 that is internally housed inside from flying debris and water droplets, for example. As examples of the external member 40, a metal or resin pipe, a resin protector, a flexible corrugated tube made of resin or the like, a rubber waterproof cover, or a combination of these can be used.

### Configuration of Electric Wire Member 20

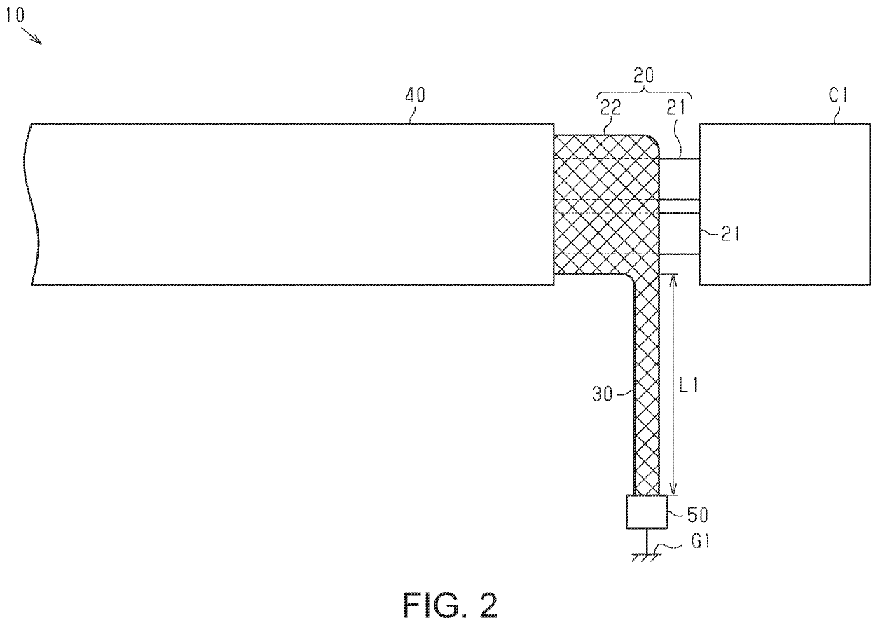

As depicted in FIG. 2, the electric wire member 20 includes one or more electric wires 21 and a braided member 22 (braided tube) that surrounds the outer circumference of the electric wires 21. The electric wire member 20 according to the present embodiment includes two electric wires 21 and one braided member 22 that collectively surrounds the two electric wires 21. Here, in the present specification, the expression “collectively surrounding a member A and a member B” means, for example, that the member A and the member B are collectively enclosed within one tubular member without a wall being provided between the member A and the member B.

As one example, each electric wire 21 is a covered electric wire with an electrically conductive core wire and an insulating coating that is electrically insulating and surrounds the outer circumference of the core wire. Each electric wire 21 is a high-voltage electric wire that can handle a high voltage and a large current, for example. As examples, each electric wire 21 may be a shielded electric wire with its own electromagnetic shielding structure or a non-shielded electric wire that does not have its own electromagnetic shielding structure. Each electric wire 21 in the present embodiment is a non-shielded electric wire.

End portions in the length direction of each electric wire 21 may be exposed from the external member 40, for example. The end portions in the length direction of the electric wires 21 may also be exposed from the braided member 22, for example. As one example, the connector C1 may be attached to one end of each electric wire 21 in the length direction.

As one example, the braided member 22 is formed in a tubular shape that surrounds the entire outer circumference of the plurality of electric wires 21. The braided member 22 may be flexible, for example. As examples, braided wire produced by weaving a plurality of metal strands or braided wire where metal strands and resin strands are woven in combination can be used as the braided member 22. The braided member 22 in the present embodiment is a braided wire produced by weaving a plurality of metal strands.

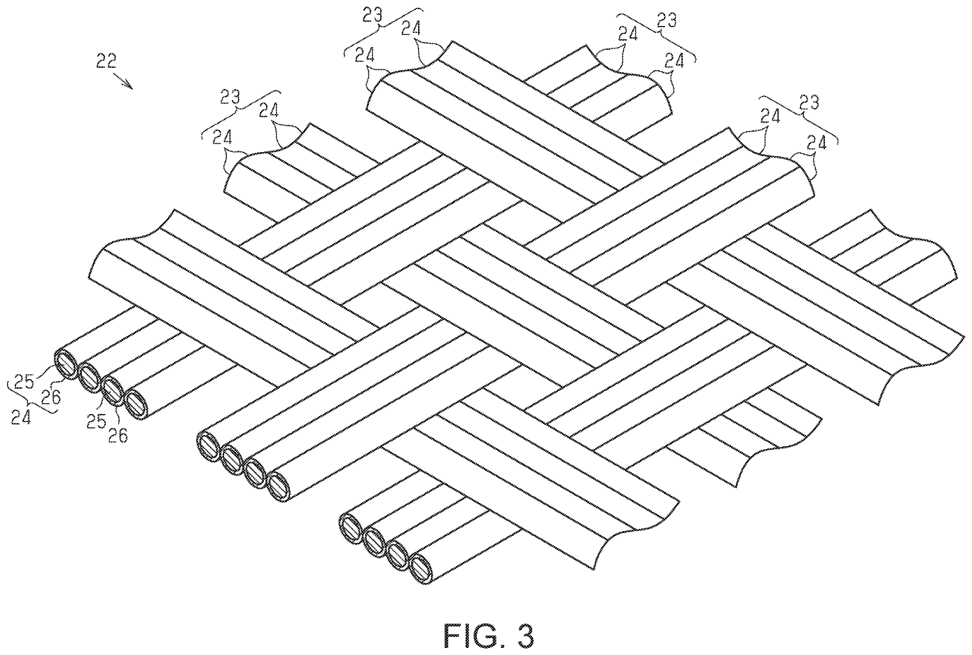

As depicted in FIG. 3, the braided member 22 has a plurality of strand bundles 23, for example. As one example, the braided member 22 is formed by braiding the plurality of strand bundles 23 into a tubular shape. As one example, the braided member 22 is formed by weaving a plurality of strand bundles 23 in a plain weave, that is, by crossing warp threads and weft threads and weaving the threads so that they alternately rise and fall. The braided member 22 has a mesh formed by two strand bundles 23 that serve as warp threads and two strand bundles 23 that serve as weft threads. Note that there are no particular limitations on the way in which the strand bundle 23 is woven and the bundle may be woven in a satin weave or twill weave, for example.

Each strand bundle 23 has a plurality of (in FIG. 3, four) metal strands 24. That is, in the braided member 22, a plurality of metal strands 24 are grouped into one set (or “pick”), which is to say, one strand bundle 23.

As one example, each metal strand 24 has a strand main body 25 and a plating film 26 that covers the outer circumferential surface of the strand main body 25. As example materials, the strand main body 25 can be made using a copper-based or aluminum-based metal material. A tin-based metal material can be used as one example of the material of the plating film 26. The cross-sectional shape of each metal strand 24 when cut on a plane that is perpendicular to the length direction of the metal strand 24, that is, the transverse cross-sectional shape of each metal strand 24 may be any freely chosen shape. As examples, the cross-sectional shape of each metal strand 24 may be circular, semicircular, polygonal, square, or a flattened shape. In the present embodiment, the transverse cross-sectional shape of each metal strand 24 is circular.

The strand main body 25 is provided at the center of the metal strand 24. The plating film 26 covers the outer circumferential surface of the strand main body 25 around the entire circumference. The surface roughness of the outer circumferential surface of the plating film 26 is greater than the surface roughness of the outer circumferential surface of the strand main body 25, for example.

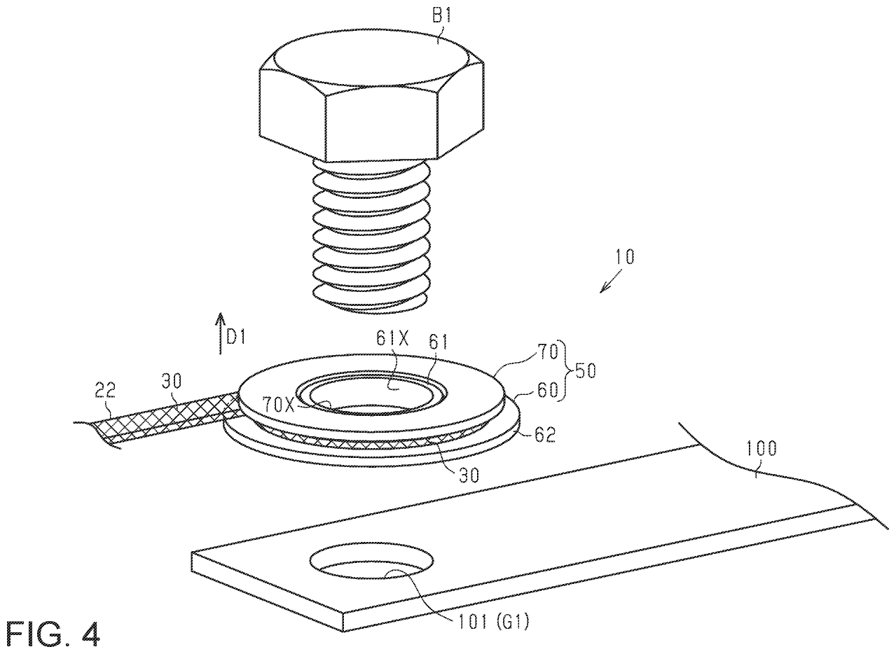

As depicted in FIG. 2, a first end in the axial direction of the braided member 22 is exposed from the external member 40. The first end in the axial direction of the braided member 22 includes an earth wire 30 that does not surround the outer circumference of the electric wire 21 and extends away from the electric wire 21. This earth wire 30 is part of the braided member 22. As one example, the earth wire 30 extends in a direction (downward in the drawing) that intersects the length direction of the electric wires 21. The front end of the earth wire 30 is electrically connected to an earth terminal 50 made of metal. As one example, the earth terminal 50 is electrically connected to a grounding point G1 provided on a vehicle body panel 100 (see FIG. 4). The front end of the earth wire 30 is connected to the grounding point G1 via the earth terminal 50, for example. Here, the length from the base end of the earth wire 30 to the earth terminal 50 is set at a length L1. The length L1 also corresponds to the length from the base end of the earth wires 30 to the grounding point G1. The “front end” of the earth wire 30 is the end of the earth wire 30 in the axial direction that is farthest from the electric wire 21. The “base end” of the earth wire 30 is the end of the earth wire 30 in the axial direction that is farthest from the earth terminal 50.

Although not illustrated, out of the two ends in the axial direction of the braided member 22, a second end which is at the opposite end to the first end is earthed via the connector C2 (see FIG. 1) for example at a grounding point provided on a vehicle body panel or the like. Note that in the same way as the first end of the braided member 22, the second end of the braided member 22 may be earthed at a grounding point via an earth wire 30 and an earth terminal 50.

### Configuration of Earth Terminal 50

As depicted in FIGS. 4, 5, 6 and 7, the earth terminal 50 includes a base member 60 (base) made of metal and a cover member 70 (cover) made of metal. As one example, the base member 60 is a separate component from the cover member 70. As example materials, the base member 60 and the cover member 70 may be made of a metal material such as copper, copper alloy, aluminum, aluminum alloy, or stainless steel. The base member 60 and the cover member 70 may be made of the same metal material or may be different metal materials.

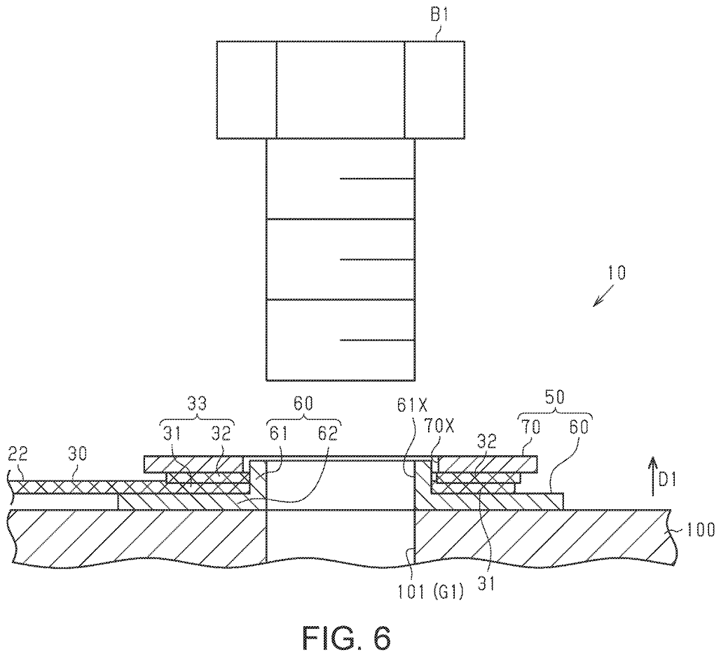

As depicted in FIGS. 4 and 6, the earth terminal 50 is fixed to the vehicle body panel 100, for example. Here, the vehicle body panel 100 is provided with a fixing hole 101 for fixing the earth terminal 50 to the vehicle body panel 100 using a bolt B1, for example. The fixing hole 101 functions as the grounding point G1. The vehicle body panel 100 is made of metal. Example materials that can be used for the vehicle body panel 100 include copper-based, aluminum-based, and iron-based metal materials.

### Configuration of Base Member 60

The base member 60 includes a column portion 61 around which the earth wire 30 of the braided member 22 is wound, and a flange portion 62 (flange). As depicted in FIG. 6, the base member 60 is a single component in which the column portion 61 and the flange portion 62 are continuously and integrally formed.

As one example, the column portion 61 is formed so as to protrude in a first direction D1 (here, upward) from one surface (here, the upper surface) of the flange portion 62. As one example, the column portion 61 is a cylindrical portion with a hollow structure. That is, the column portion 61 is a cylindrical portion with a through hole 61X that passes through the column portion 61 in the axial direction (here, the first direction D1). The through hole 61X is formed so that the bolt B1 can be passed through, for example. The through hole 61X is provided so as to overlap the fixing hole 101 of the vehicle body panel 100 in a plan view from the first direction D1, for example. Here, the first direction D1 is a direction that extends parallel to the axial direction (or height direction) of the column portion 61.

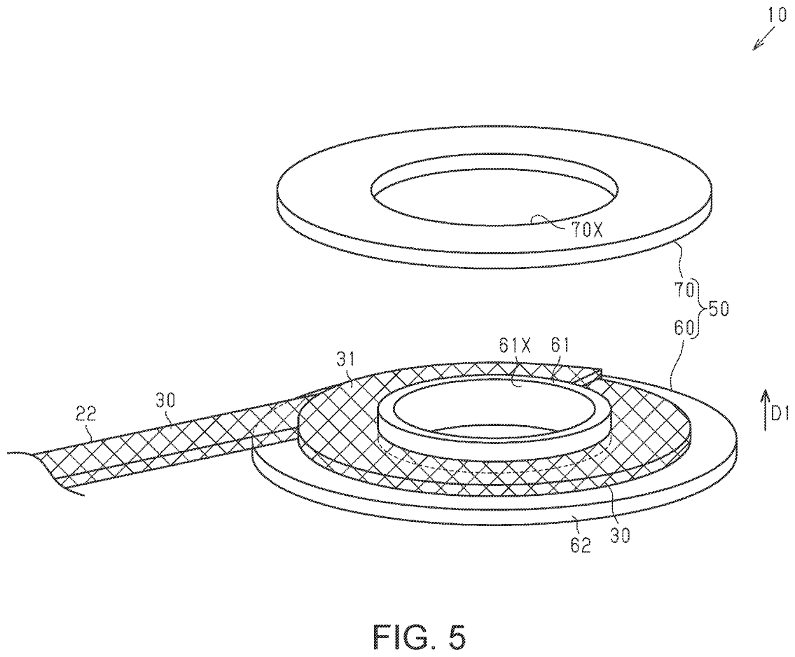

The shape of a transverse cross-section around the outer circumferential surface of the column portion 61 may be any freely chosen shape. The transverse cross-sectional shape around the inner circumferential surface of the through hole 61X may also be any freely chosen shape. As depicted in FIG. 5, the transverse cross-sectional shape around the outer circumferential surface of the column portion 61 according to the present embodiment is circular. The transverse cross-sectional shape around the inner circumferential surface of the through hole 61X according to the present embodiment is also circular. In other words, the planar shape of the column portion 61 is circular, and the planar shape of the through hole 61X when looking from above is also circular. That is, the column portion 61 according to the present embodiment is formed in the shape of a circular cylinder. In this specification, the expression “in plan view” refers to when an object is viewed from a first direction D1, and the expression “planar shape” refers to when the shape of an object is viewed from the first direction D1.

As depicted in FIG. 6, one example of the flange portion 62 is formed so as to protrude radially outward from the outer circumferential surface of the column portion 61. As one example, the flange portion 62 is provided at one end in the axial direction of the column portion 61. As depicted in FIG. 5, one example of the flange portion 62 is formed continuously around the entire circumferential direction of the outer circumferential surface of the column portion 61. The planar shape of the flange portion 62 is formed larger than the planar shape of the column portion 61. The planar shape of the flange portion 62 may be any freely chosen shape. The planar shape of the flange portion 62 may be the same as the planar shape of the column portion 61, or may be different from the planar shape of the column portion 61. The flange portion 62 of the present embodiment has a circular planar shape that is the same as the planar shape of the column portion 61. The flange portion 62 in the present embodiment is formed in an overall disk shape. In the present specification, the expression “disk shape” refers to a form whose planar shape is circular and has a certain thickness. Note that the thickness relative to the diameter does not matter for this “disk shape”. The expression “disk shape” also includes shapes in which convexes and concaves are partially formed.

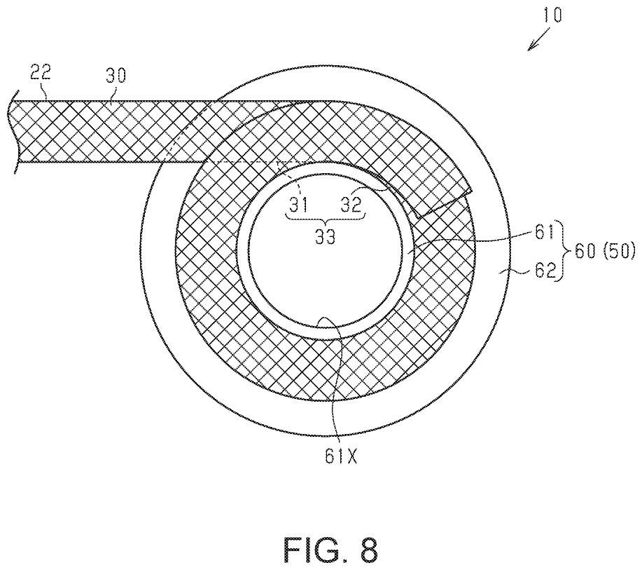

As depicted in FIG. 8, the earth wire 30 of the braided member 22 is wound around the outer circumference of the column portion 61 of the base member 60. The earth wire 30 is wound around the outer circumference of the column portion 61 along the outer circumference of the column portion 61. As one example, the earth wire 30 is wound over a range that is longer than one revolution around the outer circumference of the column portion 61. As one example, the earth wire 30 is wound around the outer circumference of the column portion 61 in a spiral shape. As one example, the earth wire 30 is wound around the outer circumference of the column portion 61 so that the second turn part 32 overlaps the first turn part 31. In other words, the earth wire 30 has an overlapping portion 33 (overlap) where the first turn part 31 (first turn) and the second turn part 32 (second turn) wound around the outer circumference of the column portion 61 overlap. As depicted in FIG. 6, in this overlapping portion 33, the first turn part 31 and the second turn part 32 overlap in the first direction D1. In this way, in the overlapping portion 33, the earth wire 30 is overlapped two or more times in the first direction D1. As depicted in FIG. 8, the overlapping portion 33 may be provided at only one part of the circumferential direction of the column portion 61, for example. As one example, the overlapping portion 33 may be formed so as to extend by a length in the circumferential direction of the column portion 61 that is less than ½ of the circumference of the column portion 61. The earth wire 30 wound around the outer circumference of the column portion 61 is provided on the flange portion 62. Note that the cover member 70 is depicted in perspective in FIG. 8.

### Configuration of Cover Member 70

As depicted in FIGS. 4 and 5, the cover member 70 includes an insertion hole 70X into which the column portion 61 is inserted. As one example, the insertion hole 70X passes through the cover member 70 in the thickness direction (here, the first direction D1). The insertion hole 70X is provided in the center of the cover member 70 in plan view, for example. The planar shape of the insertion hole 70X can be any freely chosen shape so long as it is possible to insert the column portion 61. The planar shape of the insertion hole 70X may be the same as the planar shape of the column portion 61, or may be a different shape from the planar shape of the column portion 61. In the present embodiment, the planar shape of the insertion hole 70X is formed so as to be circular, which is the same as the planar shape of the column portion 61. The planar shape of the insertion hole 70X is formed slightly larger than the planar shape of the column portion 61.

As one example, the planar shape of the cover member 70 is smaller than the planar shape of the flange portion 62. The planar shape of the cover member 70 may be any freely chosen shape. The planar shape of the cover member 70 may be the same as the planar shape of the insertion hole 70X, or may be different from the planar shape of the insertion hole 70X. The planar shape of the cover member 70 in the present embodiment is circular, which is the same as the planar shape of the insertion hole 70X. The cover member 70 in the present embodiment is formed in the shape of a disc which includes the insertion hole 70X.

As depicted in FIG. 4, the cover member 70 is fixed to the base member 60 with the column portion 61 inserted into the insertion hole 70X. The cover member 70 is fixed to the base member 60 so as to cover the earth wire 30 wound around the column portion 61.

As depicted in FIGS. 5, 6 and 7, the cover member 70 is fixed to the base member 60 in a state where the earth wire 30 wound around the column portion 61 is sandwiched between the cover member 70 and the flange portion 62. As one example, the cover member 70 is fixed to the base member 60 so as to press the earth wire 30 wound around the column portion 61 toward the flange portion 62. In this state, the earth wire 30 wound around the column portion 61 may for example be compressed in the first direction D1 between the cover member 70 and the flange portion 62. As one example, the overlapping portion 33 is compressed in the first direction D1 between the flange portion 62 and the cover member 70 so that the second turn part 32 of the earth wire 30 bites into the first turn part 31 of the earth wire 30.

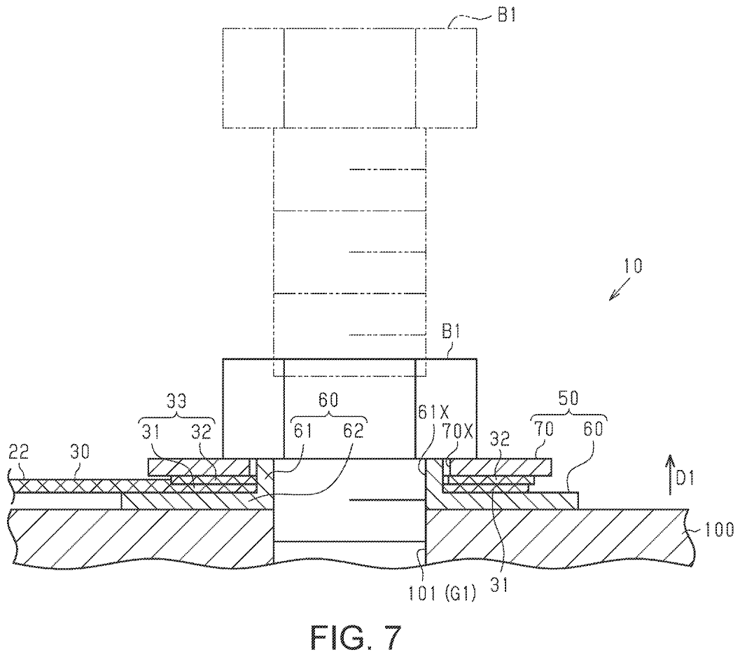

As depicted in FIGS. 6 and 7, as one example, the cover member 70 is fixed to the base member 60 by a bolt B1 that is inserted through the through hole 61X of the column portion 61 and the fixing hole 101 of the vehicle body panel 100 and then screwed into a nut, not depicted. By doing so, the cover member 70 is pressed by the head portion of the bolt B1 and thereby fixed to the fixing hole 101 of the vehicle body panel 100 and also fixed to the base member 60 in a state where the earth wire 30 is pressed toward the flange portion 62.

As described above, the earth terminal 50 is fixed to the fixing hole 101 of the vehicle body panel 100 by the bolt B1 and a nut, for example. In this state, the braided member 22 becomes electrically connected to the earth terminal 50 via the earth wire 30 wound around the column portion 61. In addition, the earth wire 30 of the braided member 22 is electrically connected via the earth terminal 50 and the bolt B1 to the grounding point G1 on the vehicle body panel 100.

Next, the effects of the present embodiment will be described.

(1) The wire harness 10 is equipped with the electric wires 21, a tubular braided member 22 that surrounds the outer circumference of the electric wires 21, and the earth terminal 50. Ends of the braided member 22 each include the earth wire 30 that does not surround the outer circumference of the electric wires 21 and extends away from the electric wires 21. The earth terminal 50 is attached to the front end of this earth wire 30. The earth terminal 50 includes the metal base member 60, which includes the column portion 61 around which the earth wire 30 is wound and the flange portion 62 that is formed integrally with the column portion 61, and a metal cover member 70 including the insertion hole 70X into which the column portion 61 is inserted. The cover member 70 is fixed to the base member 60 in a state where the earth wire 30, which has been wound around the column portion 61, is sandwiched between the cover member 70 and the flange portion 62.

With this configuration, the earth wire 30 of the braided member 22 is wound around the column portion 61 of the base member 60, and the wound earth wire 30 is sandwiched between the cover member 70 and the flange portion 62, which are both made of metal. By doing so, it is possible to electrically connect the earth wire 30 wound around the column portion 61 and the earth terminal 50. However, variations in the length of the earth wire 30 may occur during manufacturing of the wire harness 10 or the like. As one example, there may be variations in the length by which the earth wire 30 exceeds a standard dimension. Even if this happens, the excess length of the earth wire 30 can be easily accommodated by changing the length of the earth wire 30 wound around the column portion 61. By doing so, even if there are variations in the length of the earth wire 30, such variations can be easily absorbed, thereby favorably suppressing variations in the length L1 from the base end of the earth wire 30 to the earth terminal 50. In other words, the length L1 from the base end of the earth wire 30 to the earth terminal 50 can be easily set at the standard dimension. This makes it possible to favorably suppress variations in the electromagnetic shielding performance of the braided member 22.

(2) Conventional wire harnesses use a configuration where part of a braided member that has been separated from the electric wires is crimped to an earth terminal. This means that if the size of the braided member changes, it will be necessary to also change the size of the barrel portion of the earth terminal.

On the other hand, with the wire harness 10 according to the present embodiment, the earth wire 30 of the braided member 22 is sandwiched between the flange portion 62 of the base member 60 and the cover member 70. This means that even if the size of the braided member 22 is changed, the earth wire 30 of the braided member 22 can be favorably sandwiched between the base member 60 and the cover member 70 without changing the sizes of the base member 60 and the cover member 70. By doing so, it is possible to commonly use a single type of earth terminal 50 for braided members 22 of a plurality of sizes. Accordingly, since it is not necessary to fabricate a new earth terminal 50 when the size of the braided member 22 changes, the manufacturing cost of the wire harness 10 can be reduced.

(3) The earth wire 30 is wound around the outer circumference of the column portion 61 so as to have an overlapping portion 33 where the first turn part 31 and the second turn part 32 wound around the outer circumference of the column portion 61 overlap each other. Since the first turn part of the earth wire 30 and the second turn part of the earth wire 30 will overlap each other at this overlapping portion 33, the earth wire 30, that is, the braided member 22, will come into contact with itself at a large number of points. Since friction occurs at this large number of contact points, the earth wire 30 is less susceptible to coming undone from the state where the earth wire 30 is wound around the column portion 61. By doing so, it is possible to favorably keep the earth wire 30 wound around the column portion 61, and to favorably keep the earth wire 30 sandwiched and fixed between the base member 60 and the cover member 70. As a result, the force that fixes the earth terminal 50 to the earth wire 30 can be improved. This means that the state where the earth wire 30 and the earth terminal 50 are electrically connected to each other can be favorably maintained, and the reliability of the electrical connection between the earth wire 30 and the earth terminal 50 can be improved.

(4) The plating film 26 is formed on the surface of each metal strand 24 that constructs the braided member 22, which increases the surface roughness of the outer circumferential surface of each metal strand 24. This makes it possible to increase the coefficient of friction of the outer circumferential surface of each metal strand 24. This increases the frictional force between the metal strands 24 and between the metal strands 24 and the earth terminal 50 (specifically the column portion 61, the flange portion 62, and the cover member 70). As a result, the earth wire 30 is less susceptible to coming undone from the state where the earth wire 30 is wound around the column portion 61. By doing so, the earth wire 30 can be favorably maintained in a state in which the earth wire 30 is wound around the column portion 61, and the state where the earth wire 30 is sandwiched and fixed between the base member 60 and the cover member 70 can be favorably maintained. As a result, the force that fixes the earth terminal 50 to the earth wire 30 can be improved.

(5) The bolt B1, which is a fixing member, can be used to favorably fix the cover member 70 onto the base member 60. By doing so, it is possible to favorably maintain the state where the earth wire 30 is sandwiched between the base member 60 and the cover member 70, and possible to favorably maintain the state where the earth wire 30 and the earth terminal 50 are electrically connected to each other.

(6) The bolt B1 also functions as a fixing member that fixes the earth terminal 50 to the fixing hole 101, which is the grounding point G1. In other words, the bolt B1 has both a function of fixing the cover member 70 to the base member 60 and a function of fixing the earth terminal 50 to the grounding point G1. This means that the number of components of the wire harness 10 can be reduced compared to a configuration where a fixing member that fixes the cover member 70 onto the base member 60 and a fixing member that fixes the earth terminal 50 to the grounding point G1 are configured as separate components.

(7) In addition, by fixing the bolt B1 into the fixing hole 101, the earth wire 30 can be clamped and fixed, that is, the fixing of the cover member 70 to the base member 60 can be performed at the same time as the electrical connecting of the earth terminal 50 and the grounding point G1. This makes it possible to reduce the number of work steps compared to when the work of fixing the cover member 70 to the base member 60 and the work of electrically connecting the earth terminal 50 and the grounding point G1 are performed separately.

(8) Conventional wire harnesses require special equipment, that is, a crimping machine and a die, for connecting the braided member to the earth terminal by crimping. In contrast, with the wire harness 10 according to the present embodiment, by merely fixing the bolt B1 to the fixing hole 101, the cover member 70 can be fixed to the base member 60 in a state where the earth wire 30 is sandwiched between the base member 60 and the cover member 70. This means that there is no need to provide dedicated equipment for connecting the earth terminal 50 to the earth wire 30. Accordingly, the manufacturing cost of the wire harness 10 can be reduced.

(9) Also, when using a crimping machine to crimp the braided member to the earth terminal, the presence of the safety cover of the machine used during crimping means that extra length is needed, so that the part of the braided member separated from the electric wires becomes longer. In contrast, with the wire harness 10 according to the present embodiment, since the earth terminal 50 can be connected to the earth wire 30 using the bolt B1, no extra workpiece length is required to perform the connecting process. This means that with the wire harness 10, the length L1 from the base end of the earth wire 30 to the earth terminal 50 can be easily reduced.

### Other Embodiments

The embodiment described above can be modified as described below. The embodiment described above and the following modifications can be implemented in combination within a range that remains technically consistent.

In the embodiment described above, there are no particular limitations on the length of the earth wire 30 wound around the outer circumference of the column portion 61. As one example, the earth wire 30 may be wound around the outer circumference of the column portion 61 over a range of two or more turns.

Although the earth wire 30 is wound around the outer circumference of the column portion 61 in the embodiment described above so as to include the overlapping portion 33, the present disclosure is not limited to this.

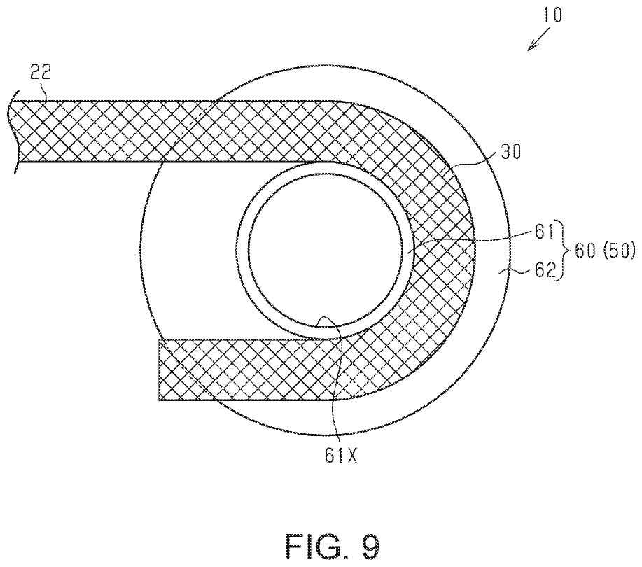

As one example, as depicted in FIG. 9, the earth wire 30 may be wound around the outer circumference of the column portion 61 in a range of less than one complete turn. As one example, the earth wire 30 may be wound around the outer circumference of the column portion 61 in a U-shape.

The structure of the earth terminal 50 in the embodiment described above may be modified as appropriate. As one example, the structure of the earth terminal 50 may be modified as appropriate as long as the cover member 70 can be fixed to the base member 60 in a state where the earth wire 30 wound around the column portion 61 is sandwiched between the base member 60 and the cover member 70.

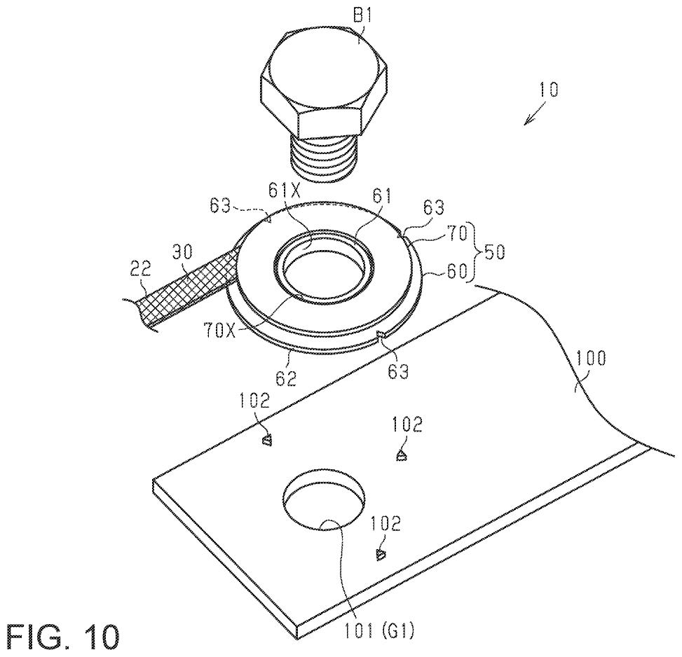

As one example, as depicted in FIG. 10, notches 63 for positioning the earth terminal 50 relative to an object to which the earth terminal 50 is attached may be provided on the outer circumferential surface of the flange portion 62. In this modification, three notches 63 are provided on the outer circumferential surface of the flange portion 62. Each notch 63 is formed so as to be recessed from the outer circumferential surface of the flange portion 62 toward the column portion 61, for example. In this modification, the vehicle body panel 100 to which the earth terminal 50 is to be attached is provided with protrusions 102. With this configuration, when fixing the earth terminal 50 to the vehicle body panel 100, by disposing the earth terminal 50 on the vehicle body panel 100 so that the notches 63 and the protrusions 102 engage one another, it is possible to easily position the earth terminal 50 relative to the vehicle body panel 100. By doing so, it is possible to facilitate the work of fixing the earth terminal 50 to the vehicle body panel 100.

Although the column portion 61 is formed of a hollow structure with the through hole 61X in the embodiment described above, the present disclosure is not limited to this. As one example, the column portion 61 may be formed of a solid structure. In this case, the through hole 61X is omitted. Also with this configuration, a through hole into which the bolt B1 for fixing the earth terminal 50 to the fixing hole 101 is inserted is provided separately from the column portion 61.

Although the transverse cross-sectional shape around the outer circumferential surface of the column portion 61 is circular in the embodiment described above, the present disclosure is not limited to this. As one example, the transverse cross-sectional shape around the outer circumferential surface of the column portion 61 may be polygonal. As examples of this, the column portion 61 may be formed as a square column or a square tube. In this case, it is preferable for the outer circumferential surface of the column portion 61 to be formed with ridge portions that are chamfered or rounded. Since ridge portions are provided on the outer circumferential surface of the column portion 61 in this modification, the earth wire 30 is likely to catch on these ridge portions, which makes the earth wire 30 less susceptible to coming undone from the state where the earth wire 30 is wound around the column portion 61. By doing so, it is possible to favorably keep the earth wire 30 wound around the column portion 61, and the force that fixes the earth terminal 50 to the earth wire 30 can be improved.

Although the fixing member for fixing the cover member 70 onto the base member 60 is embodied as the bolt B1 in the embodiment described above, the present disclosure is not limited to this. As one example, the fixing member for fixing the cover member 70 onto the base member 60 may be embodied as a rivet.

Although the cover member 70 is fixed to the base member 60 using the bolt B1 as a fixing member in the embodiment described above, the present disclosure is not limited to this.

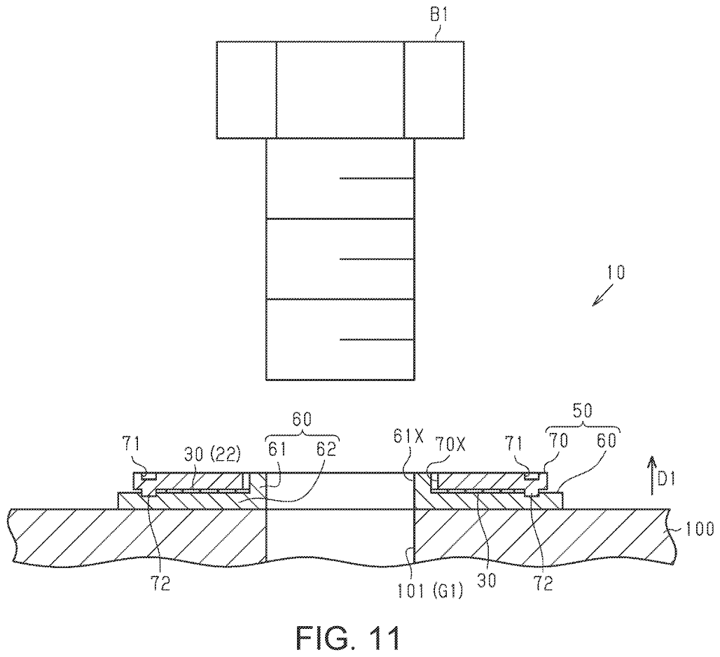

As one example, as depicted in FIG. 11, the cover member 70 may be integrated with the base member 60. As one example, the cover member 70 and the base member 60 may be integrated by press machining. As one example, the cover member 70 can be disposed on the base member 60 so as to cover the earth wire 30 wound around the outer circumference of the column portion 61, and the cover member 70 and the base member 60 can be integrated by performing press machining at a plurality of locations on the upper surface of the cover member 70. At each location where press machining is performed, a recess 71 is formed in the upper surface of the cover member 70 and a protrusion 72 is formed to protrude downward from the lower surface of the cover member 70. These protrusions 72 bite into the flange portion 62 of the base member 60, which integrates the cover member 70 and the base member 60 into a single body.

Although the earth terminal 50 is attached to the earth wire 30 provided at the end of the braided member 22, which is a collective shielding member that collectively surrounds the plurality of electric wires 21, in the embodiment described above, the present disclosure is not limited to this. As one example, the earth terminal 50 may be attached to earth wires provided at the ends of the braided members (that is, the respective core shield members) of the shielded wires. Note that as one example, each shielded electric wire is composed of an electric wire 21, a braided member which is a core shielding member that surrounds the outer circumference of the electric wire 21, and a sheath that surrounds the outer circumference of the braided member.

The external member 40 in the embodiment described above may be omitted.

Although the electric wire member 20 is composed of two electric wires 21 and the braided member 22 in the embodiment described above, the present disclosure is not limited to this. The number of electric wires 21 that construct the electric wire member 20 can be changed in keeping with the specification of the vehicle V. As examples, the number of electric wires 21 that compose the electric wire member 20 may be one, or three or more.

Although the grounding point G1 is embodied as the fixing hole 101 in the vehicle body panel 100 in the embodiment described above, the present disclosure is not limited to this. As one example, the grounding point G1 may be embodied as a stud bolt provided on the vehicle body panel 100. In this case, as one example, the stud bolt is inserted into the through hole 61X of the earth terminal 50. A stud bolt can also function as a fixing member for fixing the cover member 70 onto the base member 60.

Although the plurality of vehicle-mounted devices that are electrically connected to the wire harness 10 are the high-voltage battery M1 and the inverter M2 in the embodiment described above, the present disclosure is not limited to this. There are no particular limitations on the plurality of vehicle-mounted devices electrically connected to the wire harness 10 so long as such devices are mounted in the vehicle V.

The relative positions of the high-voltage battery M1 and the inverter M2 in the vehicle V are not limited to the positions described in the above embodiment and may be changed as appropriate in keeping with the configuration of the vehicle V.

In the embodiment described above, the planar shape of the insertion hole 70X of the cover member 70 may match the planar shape of the column portion 61 of the base member 60 and the inner diameter of the insertion hole 70X of the cover member 70 may match the outer diameter of the column portion 61 of the base member 60. The column portion 61 of the base member 60 may have a size and shape that enables friction fitting of the column portion 61 to the insertion hole 70X of the cover member 70. As depicted in FIG. 5, the insertion hole 70X of the cover member 70 may have a smooth inner circumferential surface, and the column portion 61 of the base member 60 may have a smooth outer circumferential surface.

In the illustrated embodiment, the earth wire 30 may be referred to as a “conductive braided strip”. The flange portion 62 and the cover member 70 in the illustrated embodiment may be referred to as a “flat disc pair” that are configured to sandwich a conductive braided strip, which may be the earth wire 30. The earth terminal 50 in the illustrated embodiment may be referred to as a “bobbin-type earth terminal” or a conductive bobbin” that as examples can be configured so that a conductive braided strip can be wrapped around it or can sandwich a conductive braided strip between flat disks.

Like the non-limiting examples depicted in FIGS. 4 to 7, 10, and 11, the height of the column portion 61, the thickness of the earth terminal 50, or the shortest distance between the flange portion 62 and the cover member 70 may be smaller than the distance by which the flange portion 62 or the cover member 70 protrudes in the radial direction.

Like the non-limiting examples depicted in FIGS. 4 to 7, 10 and 11, the diameter or maximum diameter of the flange portion 62 of the earth terminal 50 may be larger than the diameter or maximum diameter of the cover member 70.

All features of the embodiments disclosed here are exemplary and should not be regarded as limitations on the present disclosure. The scope of the present disclosure is indicated by the range of the patent claims, not the description given above, and is intended to include all changes within the meaning and scope of the patent claims and their equivalents.

1. A wire harness comprising:
an electric wire:
a braided tube that is tubular and that surrounds an outer circumference of the electric wire; and
an earth terminal, wherein:
an end of the braided tube includes an earth wire that does not surround the outer circumference of the electric wire and extends away from the electric wire,
the earth terminal is attached to a front end of the earth wire,
the earth terminal includes:
a base that is made of metal and that includes a column around which the earth wire is wound and a flange that is integrally formed with the column; and
a cover that is made of metal and that includes an insertion hole into which the column is inserted, and
the cover is fixed to the base with the earth wire, which is wound around the column, sandwiched between the cover and the flange.

2. The wire harness according to claim 1, wherein:
the earth wire is wound around an outer circumference of the column over a range that exceeds one revolution, and
the earth wire includes an overlap where a first turn and a second turn that are wound around the outer circumference of the column overlap.

3. The wire harness according to claim 1, wherein:
the earth wire is wound around an outer circumference of the column over a range of less than one revolution, and
the earth wire is wound around the outer circumference of the column in a U-shape.

4. The wire harness according to claim 1, wherein:
the braided tube has a structure in which a plurality of metal strands are woven,
each metal strand of the plurality of metal strands includes a strand main body and a plating film that covers an outer circumferential surface of the strand main body, and
a surface roughness of an outer circumferential surface of the plating film is greater than a surface roughness of the outer circumferential surface of the strand main body.

5. The wire harness according to claim 1,
further comprising a fixing member that fixes the cover onto the base.

6. The wire harness according to claim 5, wherein:
the column is tubular with a through hole that passes through the column in an axial direction, and
the fixing member is a bolt that is inserted into the through hole and that fixes the earth terminal to a grounding point.

7. The wire harness according to claim 1, wherein the cover is integrated with the base.

8. The wire harness according to claim 1,
wherein an outer circumferential surface of the flange includes a notch that is configured to position the earth terminal relative to an object to which the earth terminal is attached.

9. The wire harness according to claim 1,
further comprising a plurality of electric wires that includes the electric wire,
the braided tube collectively surrounds an outer circumference of the plurality of electric wires, and
the earth wire does not surround the outer circumference of the plurality of electric wires and extends away from the plurality of electric wires.
